(19) United States
(12) Patent Application Publication
(10) Pub. No.: US 2024/0292728 A1
(43) Pub. Date: Aug. 29, 2024

(54) MANUFACTURING DEVICE OF DISPLAY DEVICE AND MANUFACTURING METHOD OF DISPLAY DEVICE

(71) Applicant: Japan Display Inc., Tokyo (JP)

(72) Inventors: Yuki HAMADA, Tokyo (JP); Takanobu TAKENAKA, Tokyo (JP); Hirofumi MIZUKOSHI, Tokyo (JP); Masaru TAKAYAMA, Tokyo (JP)

(73) Assignee: Japan Display Inc., Tokyo (JP)

(21) Appl. No.: 18/424,968

(22) Filed: Jan. 29, 2024

(30) Foreign Application Priority Data
Feb. 28, 2023 (JP) 2023-029620

(51) Int. Cl. H10K 71/16

(52) U.S. Cl. CPC H10K 71/164

(57) ABSTRACT

According to one embodiment, a manufacturing device includes a first evaporation chamber including first and second evaporation sources located between a first conveyance path and a second conveyance path for conveying a processing substrate. The first evaporation source is configured to emit a material to the first conveyance path. The second evaporation source is configured to emit a material to the second conveyance path. The manufacturing device further includes a first rotation chamber including a rotation mechanism which rotates while holding the processing substrate carried out of the first conveyance path of the first evaporation chamber, and configured to carry out the processing substrate to the second conveyance path of the first evaporation chamber.

### CROSS-REFERENCE TO RELATED APPLICATIONS

This application is based upon and claims the benefit of priority from Japanese Patent Application No. 2023-029620, filed Feb. 28, 2023, the entire contents of which are incorporated herein by reference.

### FIELD

Embodiments described herein relate generally to a manufacturing device of a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In manufacturing devices for manufacturing the display devices, the reduction in the installation space is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram showing a configuration example of a display element 20.

FIG. 11 is a diagram showing a configuration example of a manufacturing device 200.

FIG. 12 is a cross-sectional view for explaining an evaporated film DF formed by the manufacturing device 200 of FIG. 11.

FIG. 13 is a diagram showing another configuration example of the manufacturing device 200.

FIG. 14 is a diagram for explaining an upper electrode UE formed by the manufacturing device 200 of FIG. 13.

FIG. 15 is a diagram for explaining a light emitting layer EML formed by the manufacturing device 200 of FIG. 13.

FIG. 16 is a diagram showing another configuration example of the manufacturing device 200.

FIG. 17 is a diagram for explaining an upper electrode UE or a light emitting layer EML formed by the manufacturing device 200 of FIG. 16.

FIG. 18 is a diagram showing another configuration example of the manufacturing device 200.

FIG. 19 is a diagram showing a configuration example of a manufacturing device 100.

FIG. 20 is a diagram showing another configuration example of the manufacturing device 100.

FIG. 21 is a diagram showing another configuration example of a first evaporation chamber EV1.

FIG. 22 is a diagram showing another configuration example of the first evaporation chamber EV1.

### DETAILED DESCRIPTION

Embodiments described herein aim to provide a manufacturing device of a display device and a manufacturing method of a display device such that the installation space can be reduced.

In general, according to one embodiment, a manufacturing device of a display device comprises a first evaporation chamber comprising first and second evaporation sources located between a first conveyance path and a second conveyance path for conveying a processing substrate for a display device, the first evaporation source configured to emit a material to the first conveyance path, the second evaporation source configured to emit a material to the second conveyance path, and a first rotation chamber comprising a rotation mechanism which rotates while holding the processing substrate carried out of the first conveyance path of the first evaporation chamber, and configured to carry out the processing substrate to the second conveyance path of the first evaporation chamber.

According to another embodiment, a manufacturing method of a display device comprises preparing a processing substrate by forming a lower electrode above a substrate, forming a rib comprising an aperture overlapping the lower electrode, and forming a partition including a lower portion located on the rib and an upper portion located on the lower portion and protruding from a side surface of the lower portion, carrying the processing substrate in a first conveyance path of a first evaporation chamber, depositing a material emitted from a first evaporation source on the processing substrate in the first evaporation chamber, rotating the processing substrate carried out of the first evaporation chamber, carrying the processing substrate in a second conveyance path of the first evaporation chamber, depositing a material emitted from a second evaporation source to the processing substrate in the first evaporation chamber, and carrying the processing substrate out of the first evaporation chamber. The material emitted from each of the first evaporation source and the second evaporation source is a mixture including a first material and a second material. A composition ratio between the first material and the second material differs between the first evaporation source and the second evaporation source.

The Embodiments can provide a manufacturing device of a display device and a manufacturing method of a display device such that the installation space can be reduced.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

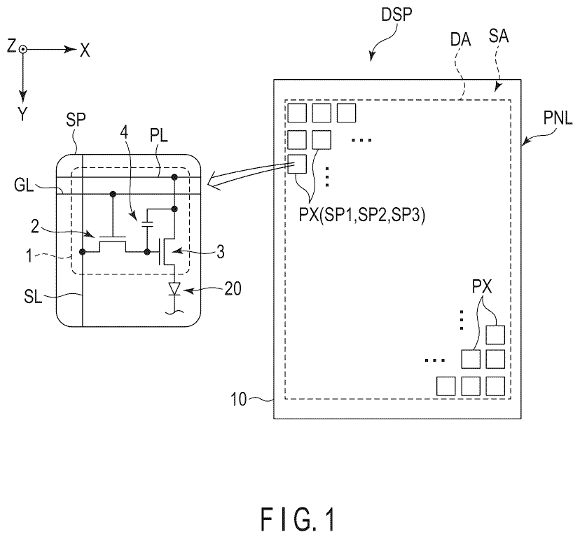

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, a terminal for connecting an IC chip and a flexible printed circuit is provided in the surrounding area SA.

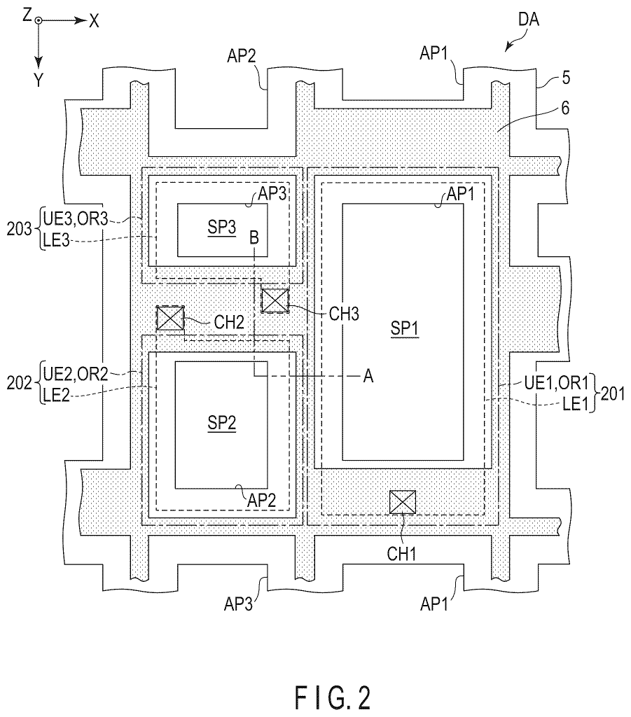

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 as seen in plan view. The partition 6 is formed into a grating shape surrounding the apertures AP1, AP2 and AP3. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the rib 5. The organic layer OR1 and the upper electrode UE1 are surrounded by the partition 6. The peripheral portion of each of the organic layer OR1 and the upper electrode UE1 overlaps the rib 5 as seen in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the rib 5. The organic layer OR2 and the upper electrode UE2 are surrounded by the partition 6. The peripheral portion of each of the organic layer OR2 and the upper electrode UE2 overlaps the rib 5 as seen in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the rib 5. The organic layer OR3 and the upper electrode UE3 are surrounded by the partition 6. The peripheral portion of each of the organic layer OR3 and the upper electrode UE3 overlaps the rib 5 as seen in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

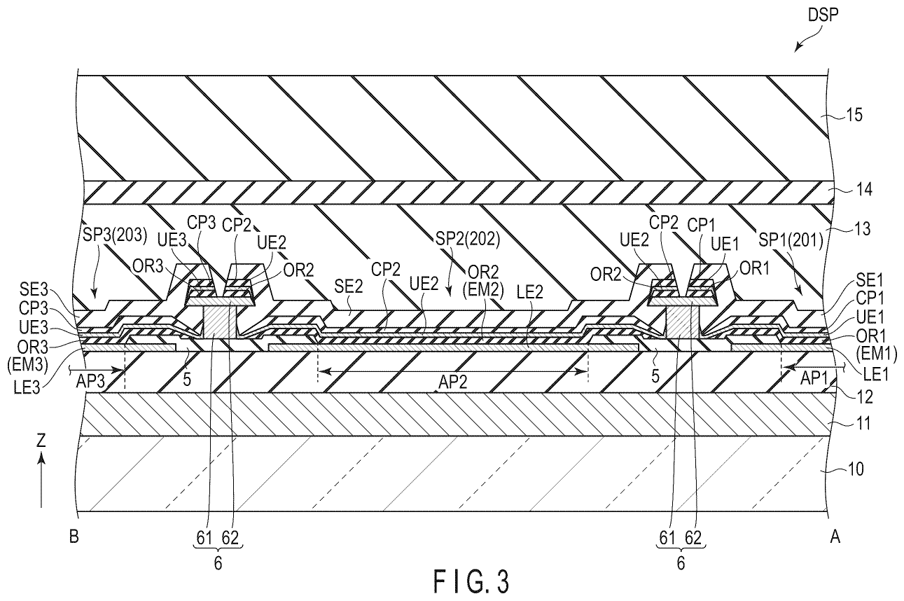

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The rib 5 is provided on the insulating layer 12 and the lower electrodes LE1, LE2 and LE3. The aperture AP1 of the rib 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the rib 5. Between, of the lower electrodes LE1, LE2 and LE3, the lower electrodes which are adjacent to each other, the insulating layer 12 is covered with the rib 5. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and HC3 of FIG. 2.

The partition 6 includes a conductive lower portion (stem) 61 provided on the rib 5 and an upper portion (cap) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the rib 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the rib 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the rib 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1.

The sealing layer SE2 is provided on the cap layer CP2, is in contact with the partition 6 and continuously covers each member of subpixel SP2.

The sealing layer SE3 is provided on the cap layer CP3, is in contact with the partition 6 and continuously covers each member of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the rib 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

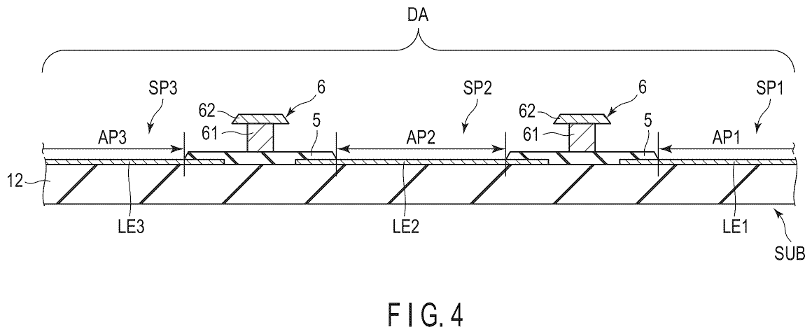

Now, this specification explains the manufacturing method of the display device DSP with reference to FIG. 4 to FIG. 9. In FIG. 4 to FIG. 9, the illustration of the lower side of the insulating layer 12 is omitted.

First, as shown in FIG. 4, a processing substrate SUB is prepared. The process of preparing the processing substrate SUB includes the process of forming the lower electrode LE1 of subpixel SP1, the lower electrode LE2 of subpixel SP2 and the lower electrode LE3 of subpixel SP3 on the insulating layer 12, the process of forming the rib 5 comprising the apertures AP1, AP2 and AP3 overlapping the lower electrodes LE1, LE2 and LE3, respectively, and the process of forming the partition 6 including the lower portion 61 provided on the rib 5 and the upper portion 62 provided on the lower portion 61 and protruding from the side surfaces of the lower portion 61. It should be noted that the partition 6 may be formed after the formation of the rib 5 comprising the apertures AP1, AP2 and AP3, or the apertures AP1, AP2 and AP3 may be formed after the formation of the partition 6.

Subsequently, the display element 201 is formed.

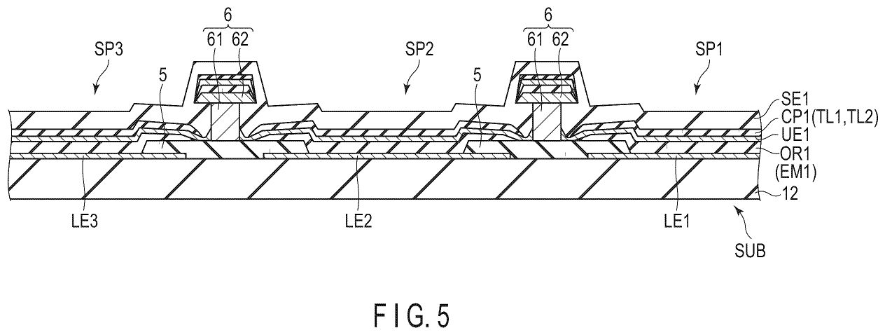

First, the processing substrate SUB is carried in a manufacturing device (in-line evaporation device) 100 as described later. Subsequently, as shown in FIG. 5, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material for forming a first transparent layer TL1 and a low-refractive material for forming a second transparent layer TL2 in series on the upper electrode UE1 using the partition 6 as a mask.

These organic layer OR1, upper electrode UE1 and cap layer CP1 are continuously formed while maintaining a vacuum environment.

Subsequently, the processing substrate SUB is carried in a chemical vapor deposition (CVD) device. The sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from evaporation sources when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

The sealing layer SE1 covers the cap layer CP1 located immediately above the partition 6, covers the cap layer CP1 located immediately above the lower electrode LE1 and is in contact with the partition 6.

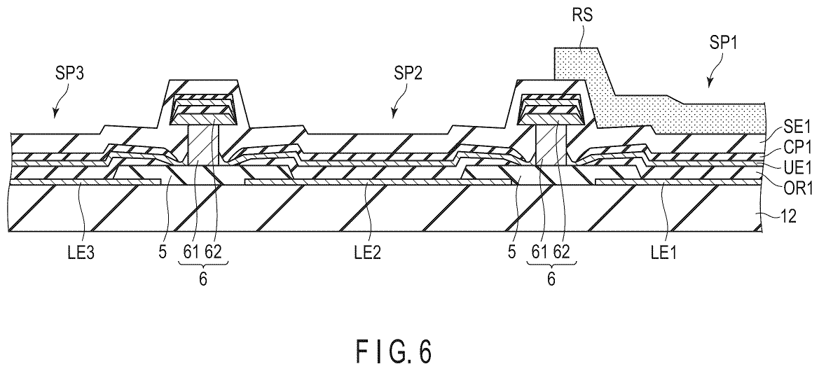

Subsequently, as shown in FIG. 6, a resist RS patterned into a predetermined shape is formed on the sealing layer SE1. The resist RS overlaps subpixel SP1 and part of the partition 6 around subpixel SP1.

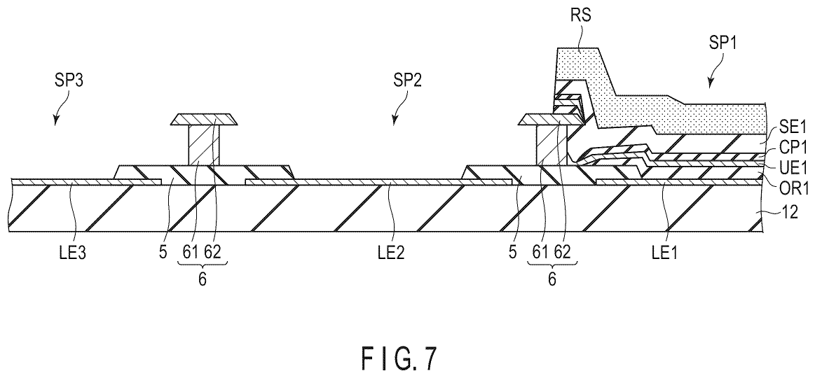

Subsequently, as shown in FIG. 7, the sealing layer SE1, cap layer CP1, upper electrode UE1 and organic layer OR1 exposed from the resist RS are removed in series by performing etching using the resist RS as a mask. In this manner, the lower electrode LE2 of subpixel SP2 and the lower electrode LE3 of subpixel SP3 are exposed.

Subsequently, the resist RS is removed. By this process, the display element 201 is formed in subpixel SP1.

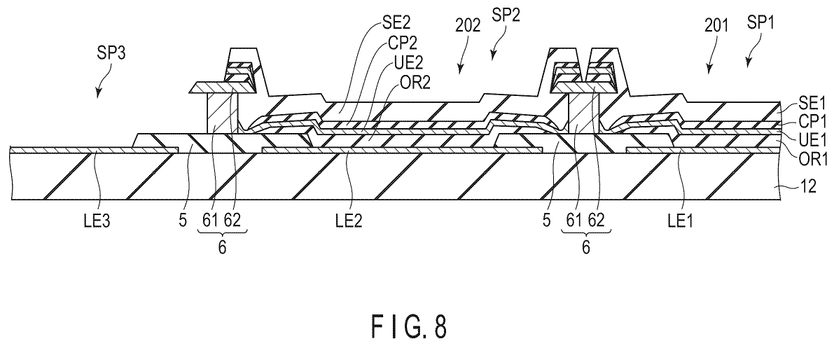

Subsequently, as shown in FIG. 8, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

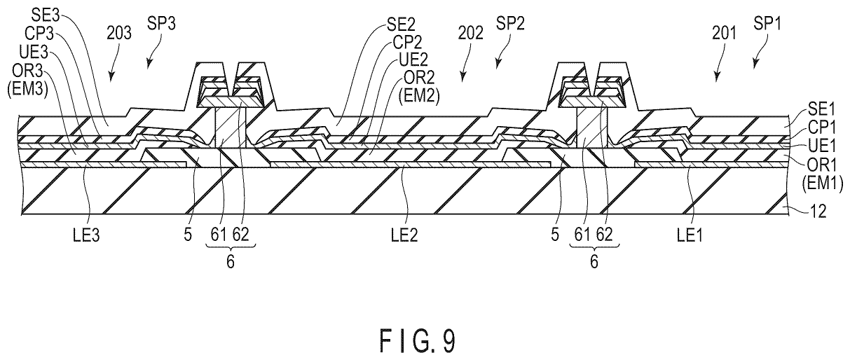

Subsequently, as shown in FIG. 9, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains a configuration example of a display element 20.

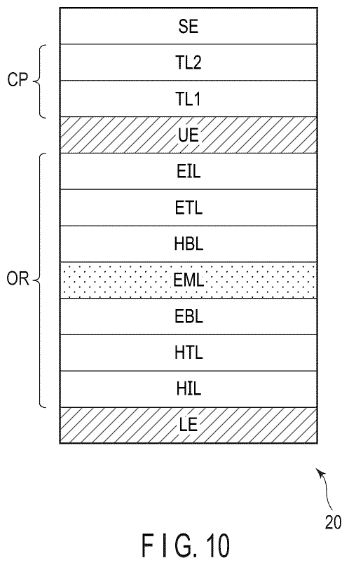

FIG. 10 is a diagram showing a configuration example of a display element 20.

The display element 20 shown in FIG. 10 could correspond to any one of the display elements 201, 202 and 203 described above.

Here, this specification explains an example in which a lower electrode LE corresponds to an anode and an upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL, an electron blocking layer EBL, a light emitting layer EML, a hole blocking layer HBL, an electron transport layer ETL and an electron injection layer EIL are stacked in this order.

It should be noted that the organic layer OR may include, in addition to the functional layers described above, other functional layers such as a carrier generation layer as needed, or at least one of the above functional layers may be omitted.

The light emitting layer EML corresponds to one of the light emitting layers EM1, EM2 and EM3 shown in FIG. 3.

A cap layer CP (CP1, CP2 or CP3) includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2.

It should be noted that the configuration of the organic layer OR is not limited to the configuration in which the organic layer OR comprises the light emitting layer EML consisting of a single layer as shown in the figure. The organic layer OR may comprise a plurality of light emitting layers.

Now, the manufacturing device 200 of the display device DSP is explained.

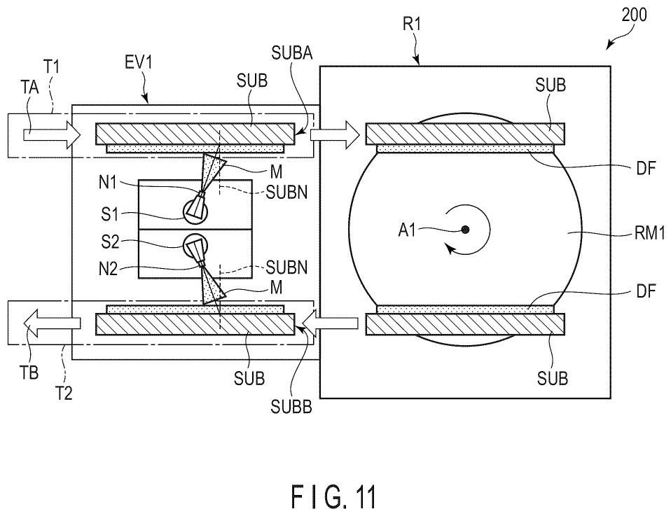

FIG. 11 is a diagram showing a configuration example of the manufacturing device 200.

The manufacturing device 200 comprises a first evaporation chamber EV1 and a first rotation chamber R1.

The first evaporation chamber EV1 comprises a first evaporation source S1 and a second evaporation source S2. The first evaporation source S1 and the second evaporation source S2 are located between first and second conveyance paths T1 and T2 in which a processing substrate SUB is conveyed. The first evaporation source S1 is configured to emit a material M to the first conveyance path T1. The second evaporation source S2 is configured to emit a material M to the second conveyance path T2.

In the first conveyance path T1, the processing substrate SUB is conveyed in conveyance direction TA shown by an arrow in the figure. In the second conveyance path T2, the processing substrate SUB is conveyed in conveyance direction TB shown by an arrow in the figure. Conveyance direction TA and conveyance direction TB are opposite directions.

The material M emitted from the first evaporation source S1 is the same as the material M emitted from the second evaporation source S2. When the material M is a mixture consisting of a plurality of types of materials, the composition ratio of the materials of the mixture may be the same in the first evaporation source S1 and the second evaporation source S2 or may differ between the first evaporation source S1 and the second evaporation source S2.

For example, the first evaporation chamber EV1 is configured to form the upper electrode UE of FIG. 10. In this case, the material M is a mixture of magnesium as the first material and silver as the second material.

As another example, the first evaporation chamber EV1 is configured to form the light emitting layer EML of FIG. 10. In this case, the material M is a mixture of a host material for carrier transport as the first material and a dopant material for light emission as the second material.

The nozzle N1 of the first evaporation source S1 and the nozzle N2 of the second evaporation source S2 incline in directions different from each other relative to the normal SUBN of the processing substrate SUB.

In the example shown in the figure, the nozzle N1 inclines so as to face an end SUBA of the processing substrate SUB in conveyance direction TA of the processing substrate SUB relative to the normal SUBN. The nozzle N2 inclines so as to face the other end SUBB of the processing substrate SUB in conveyance direction TB of the processing substrate SUB relative to the normal SUBN. Here, the end SUBA corresponds to the distal end of the processing substrate SUB located on the downstream side of conveyance direction TA. The other end SUBB corresponds to the proximal end of the processing substrate SUB located on the upstream side of conveyance direction TB.

It should be noted that the nozzle N1 may incline so as to face the other end SUBB of the processing substrate SUB, and the nozzle N2 may incline so as to face the end SUBA of the processing substrate SUB.

The first rotation chamber R1 is connected to the first evaporation chamber EV1 and is configured to convey the processing substrate SUB which was carried out of the first conveyance path T1 of the first evaporation chamber EV1 to the second conveyance path T2 of the first evaporation chamber EV1. The first rotation chamber R1 comprises a rotation mechanism RM1. The rotation mechanism RM1 holds the processing substrate SUB which was carried out of the first conveyance path T1 and is configured to rotate around a rotation axis A1. The rotation axis A1 is orthogonal to the normal SUBN of the processing substrate SUB and conveyance directions TA and TB.

In this manufacturing device 200, first, the processing substrate SUB is conveyed in conveyance direction TA and is carried in the first conveyance path T1 of the first evaporation chamber EV1. In a case where the upper electrode UE is formed in the first evaporation chamber EV1, the organic layer OR is formed on the lower electrode LE with respect to the processing substrate SUB before the processing substrate SUB is carried in the first evaporation chamber EV1. In a case where the light emitting layer EML is formed in the first evaporation chamber EV1, part of the organic layer OR (for example, the hole injection layer HIL, hole transport layer HTL and electron blocking layer EBL shown in FIG. 10) is formed on the lower electrode LE with respect to the processing substrate SUB before the processing substrate SUB is carried in the first evaporation chamber EV1.

In the first evaporation chamber EV1, the material M emitted from the first evaporation source S1 is deposited on the processing substrate SUB while the processing substrate SUB is conveyed in conveyance direction TA in the first conveyance path T1. In this manner, an evaporated film DF is formed on the surface of the processing substrate SUB.

The processing substrate SUB is carried out of the first conveyance path T1 of the first evaporation chamber EV1 and is carried in the first rotation chamber R1.

In the first rotation chamber R1, the processing substrate SUB which was carried in is held by the rotation mechanism RM1. At this time, the processing substrate SUB is held such that the evaporated film DF faces the rotation axis A1. The rotation mechanism RM1 rotates while holding the processing substrate SUB. When the first conveyance path T1 and the second conveyance path T2 are parallel to each other, the rotation mechanism RM1 rotates 180° while holding the processing substrate SUB. The rotated processing substrate SUB is located on the extended line of the second conveyance path T2 of the first evaporation chamber EV1.

Subsequently, the processing substrate SUB is carried out of the first rotation chamber R1 and is carried in the second conveyance path T2 of the first evaporation chamber EV1.

In the first evaporation chamber EV1, the material M emitted from the second evaporation source S2 is deposited on the processing substrate SUB while the processing substrate SUB is conveyed in conveyance direction TB in the second conveyance path T2. In this manner, an evaporated film DF is formed on the surface of the processing substrate SUB.

Subsequently, the processing substrate SUB is carried out of the first evaporation chamber EV1.

According to the manufacturing device 200 comprising the above configuration, two evaporated films DF having different evaporation conditions can be formed in the single first evaporation chamber EV1 while the processing substrate SUB is conveyed in one direction. In the configuration example described above, the inclination directions of the nozzles differ from each other as an example of different conditions.

Thus, compared to a configuration in which a plurality of evaporation chambers in which the inclination directions of nozzles differ from each other are connected to form evaporation films DF, the installation space of the manufacturing device 200 can be reduced, and further, the size of the manufacturing device 200 can be reduced.

Moreover, to form evaporation films DF having different evaporation conditions, a special process such as reverse conveyance of the processing substrate SUB is not needed. Thus, the retention of another processing substrate SUB on the conveyance path can be prevented.

The first and second evaporation sources S1 and S2 accommodated in the same evaporation chamber are configured to emit the same material. This configuration prevents contamination by impurities inside the evaporation chamber and can also prevent deposition of impurities on the processing substrate SUB.

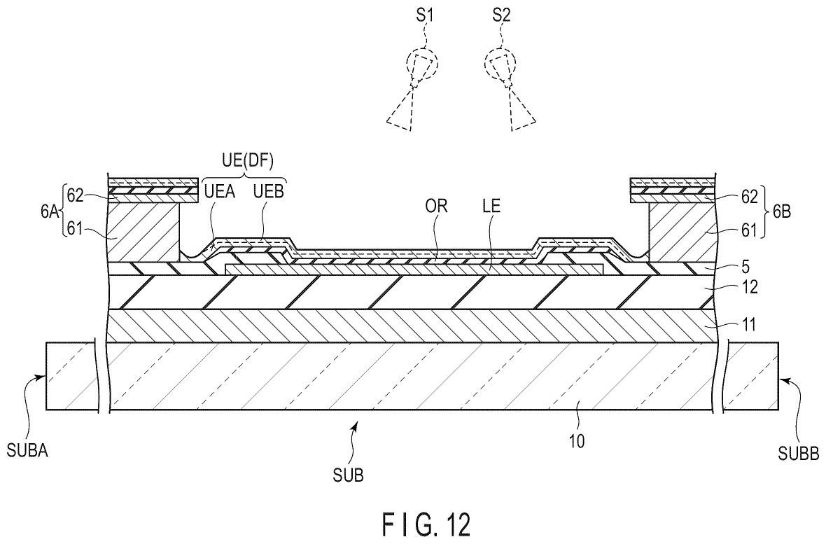

FIG. 12 is a cross-sectional view for explaining an evaporated film DF formed by the manufacturing device 200 of FIG. 11. Here, a case where an upper electrode UE is formed as the evaporated film DF is explained.

As explained with reference to FIG. 11, the first evaporation source S1 shown by broken lines inclines so as to face an end SUBA of the processing substrate SUB, and the second evaporation source S2 shown by broken lines inclines so as to face the other end SUBB of the processing substrate SUB.

Here, with respect to the partition 6, the partition 6A located on a side (the left side of the figure) close to the end SUBA relative to the lower electrode LE is distinguished from the partition 6B located on a side (the right side of the figure) close to the other end SUBB relative to the lower electrode LE.

The upper electrode UE comprises an upper electrode UEA formed firstly and an upper electrode UEB formed subsequently. The upper electrode UEA is formed of the material M emitted from the first evaporation source S1, is located on the organic layer OR and is in contact with the lower portion 61 of the partition 6A. The upper electrode UEB is formed of the material M emitted from the second evaporation source S2, is located on the upper electrode UEA and is in contact with the lower portion 61 of the partition 6B.

The upper electrode UEA is spaced apart from the lower portion 61 of the partition 6B. However, the upper electrode UEA could be in contact with the lower portion 61 of the partition 6B. The upper electrode UEB is spaced apart from the lower portion 61 of the partition 6A. However, the upper electrode UEB could be in contact with the lower portion 61 of the partition 6A.

Thus, the upper electrode UE which is in contact with the partitions 6A and 6B is formed. In this manner, common voltage can be assuredly applied to the upper electrode UE of each subpixel via the partition 6. The upper electrode UE covers the rib 5 between the partition 6 and the organic layer OR. The contact between the sealing layer which is formed later and the rib 5 is avoided. By this configuration, when the sealing layer is removed by etching, the upper electrode UE functions as an etching stopper, thereby avoiding damage to the rib 5.

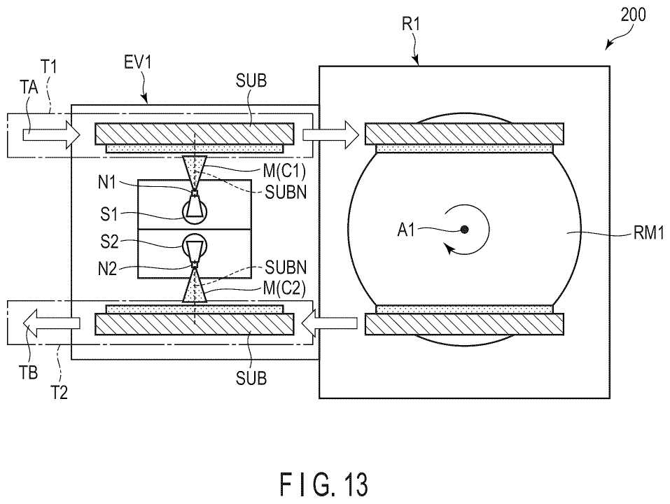

FIG. 13 is a diagram showing another configuration example of the manufacturing device 200.

The first evaporation chamber EV1 comprises the first evaporation source S1 and the second evaporation source S2 between the first conveyance path T1 and the second conveyance path T2. The first evaporation source S1 is configured to emit a material M to the first conveyance path T1. The second evaporation source S2 is configured to emit a material M to the second conveyance path T2. Both the nozzle N1 of the first evaporation source S1 and the nozzle N2 of the second evaporation source S2 are substantially parallel to the normal SUBN of the processing substrate SUB.

This manufacturing device 200 operates in the same manner as the manufacturing device 200 explained with reference to FIG. 11.

The configuration example shown in FIG. 13 is different from that shown in FIG. 11 in respect that the materials M emitted from the first and second evaporation sources S1 and S2, respectively, are mixtures each consisting of a plurality of types of materials, and the composition ratios of the materials of the mixtures are different from each other between the first evaporation source S1 and the second evaporation source S2.

For example, the first evaporation chamber EV1 is configured to form the upper electrode UE of FIG. 10. Each of the materials M is a mixture of magnesium as the first material and silver as the second material. In this case, concentration C1 of the magnesium of the mixture emitted from the first evaporation source S1 is higher than concentration C2 of the magnesium of the mixture emitted from the second evaporation source S2. In other words, the concentration of the silver of the mixture emitted from the second evaporation source S2 is higher than that of the silver of the mixture emitted from the first evaporation source S1.

As another example, the first evaporation chamber EV1 is configured to form the light emitting layer EML of FIG. 10. Each of the materials M is a mixture of a host material for carrier transport as the first material and a dopant material for light emission as the second material. In this case, concentration C1 of the host material of the mixture emitted from the first evaporation source S1 is higher than concentration C2 of the host material of the mixture emitted from the second evaporation source S2.

In a case where the first evaporation chamber EV1 is configured to form the light emitting layer EML, concentration C2 of the host material of the mixture emitted from the second evaporation source S2 could be higher than concentration C1 of the host material of the mixture emitted from the first evaporation source S1.

In the configuration example shown in FIG. 13, effects similar to those of the configuration example shown in FIG. 11 are obtained.

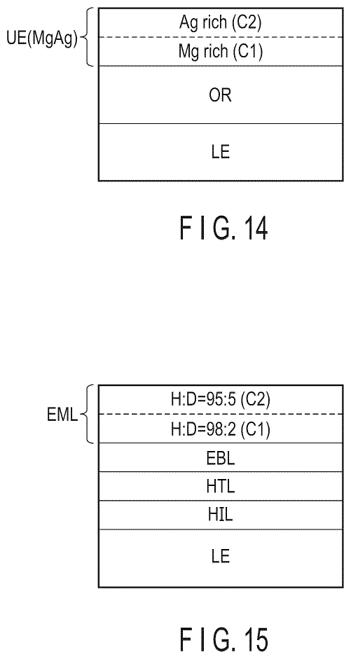

FIG. 14 is a diagram for explaining an upper electrode UE formed by the manufacturing device 200 of FIG. 13.

In an upper electrode UE formed of a mixture of magnesium and silver, a layer which is close to an organic layer OR contains much magnesium (Mg rich), and a layer which is distant from the organic layer OR contains much silver (Ag rich). The work function of magnesium is less than that of silver. Magnesium is easily damaged by moisture compared with silver.

By the upper electrode UE comprising the above configuration, the efficiency of electron injection can be improved as a layer which is close to the organic layer OR contains much magnesium in a case where the upper electrode UE functions as the cathode of the display element 20. Further, the upper electrode UE which is not easily damaged by moisture can be formed.

FIG. 15 is a diagram for explaining a light emitting layer EML formed by the manufacturing device 200 of FIG. 13.

In a light emitting layer EML formed of a mixture of a host material H and a dopant material D, the composition ratio of a layer which is close to an electron blocking layer EBL is, for example, H:D=98:2. In other words, the dopant concentration in the layer which is close to the electron blocking layer EBL is 2%.

The composition ratio of a layer which is distant from the electron blocking layer EBL is, for example, H:D=95:5. In other words, the dopant concentration in the layer which is distant from the electron blocking layer EBL is 5%.

By the light emitting layer EML comprising this configuration, the dopant concentration can be changed in the thickness direction.

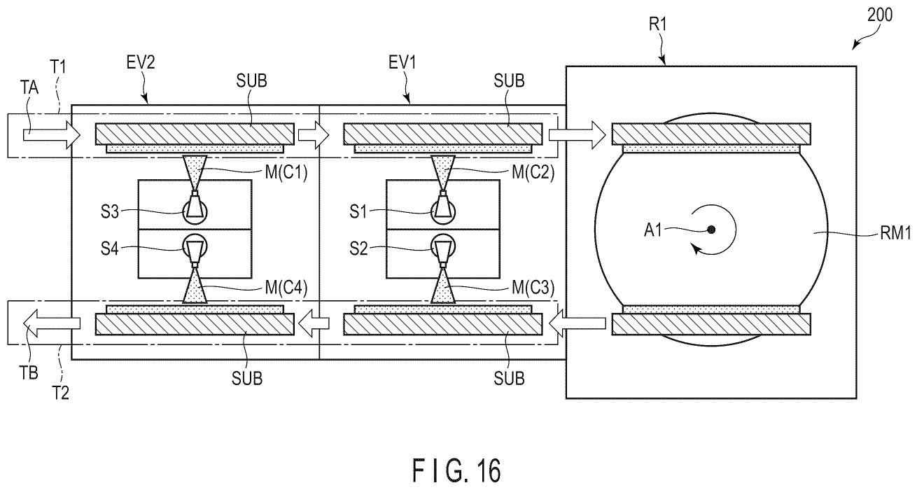

FIG. 16 is a diagram showing another configuration example of the manufacturing device 200.

The manufacturing device 200 comprises a second evaporation chamber EV2 in addition to the first evaporation chamber EV1 and first rotation chamber R1 shown in FIG. 13. The second evaporation chamber EV2 is connected to the first evaporation chamber EV1. The first evaporation chamber EV1 is provided between the first rotation chamber R1 and the second evaporation chamber EV2.

The second evaporation chamber EV2 comprises a third evaporation source S3 and a fourth evaporation source S4 between the first conveyance path T1 and the second conveyance path T2. The third evaporation source S3 is configured to emit a material M to the first conveyance path T1. The fourth evaporation source S4 is configured to emit a material M to the second conveyance path T2.

In this manufacturing device 200, first, a processing substrate SUB is conveyed in conveyance direction TA and is carried in the first conveyance path T1 of the second evaporation chamber EV2. In the second evaporation chamber EV2, the material M emitted from the third evaporation source S3 is deposited on the processing substrate SUB while the processing substrate SUB is conveyed in conveyance direction TA in the first conveyance path T1.

Subsequently, the processing substrate SUB is carried out of the first conveyance path T1 of the second evaporation chamber EV2 and is carried in the first conveyance path T1 of the first evaporation chamber EV1. In the first evaporation chamber EV1, the material M emitted from the first evaporation source S1 is deposited on the processing substrate SUB while the processing substrate SUB is conveyed in conveyance direction TA in the first conveyance path T1.

The processing substrate SUB is carried out of the first conveyance path T1 of the first evaporation chamber EV1 and is carried in the first rotation chamber R1. In the first rotation chamber R1, the processing substrate SUB which was carried in is held by the rotation mechanism RM1. The rotation mechanism RM1 rotates while holding the processing substrate SUB. The rotated processing substrate SUB is located on the extended line of the second conveyance path T2 of the first evaporation chamber EV1.

Subsequently, the processing substrate SUB is carried out of the first rotation chamber R1 and is carried in the second conveyance path T2 of the first evaporation chamber EV1. In the first evaporation chamber EV1, the material M emitted from the second evaporation source S2 is deposited on the processing substrate SUB while the processing substrate SUB is conveyed in conveyance direction TB in the second conveyance path T2.

Subsequently, the processing substrate SUB is carried out of the second conveyance path T2 of the first evaporation chamber EV1 and is carried in the second conveyance path T2 of the second evaporation chamber EV2. In the second evaporation chamber EV2, the material M emitted from the fourth evaporation source S4 is deposited on the processing substrate SUB while the processing substrate SUB is conveyed in conveyance direction TB in the second conveyance path T2.

The materials M emitted from the first evaporation source S1, the second evaporation source S2, the third evaporation source S3 and the fourth evaporation source S4 are the same as each other and are mixtures each consisting of a plurality of types of materials. The composition ratios of the materials of the mixtures of the first evaporation source S1, the second evaporation source S2, the third evaporation source S3 and the fourth evaporation source S4 are different from each other.

For example, the first evaporation chamber EV1 and the second evaporation chamber EV2 are configured to form the upper electrode UE of FIG. 10. In this case, each of the materials M is a mixture of magnesium as the first material and silver as the second material.

As another example, the first evaporation chamber EV1 and the second evaporation chamber EV2 are configured to form the light emitting layer EML of FIG. 10. In this case, each of the materials M is a mixture of a host material for carrier transport as the first material and a dopant material for light emission as the second material.

In these cases, concentration C1 of the first material of the mixture emitted from the third evaporation source S3 is higher than concentration C2 of the first material of the mixture emitted from the first evaporation source S1. Concentration C2 is higher than concentration C3 of the first material of the mixture emitted from the second evaporation source S2. Concentration C3 is higher than concentration C4 of the first material of the mixture emitted from the fourth evaporation source S4 (C4<C3<C2<C1).

It should be noted that, in a case where a light emitting layer EML is formed in the manufacturing device 200 shown in FIG. 16, concentration C4 could be higher than concentration C3, and concentration C3 could be higher than concentration C2, and concentration C2 could be higher than concentration C1 (C1<C2<C3<C4).

In the configuration example shown in FIG. 16, effects similar to those of the configuration example shown in FIG. 11 are obtained.

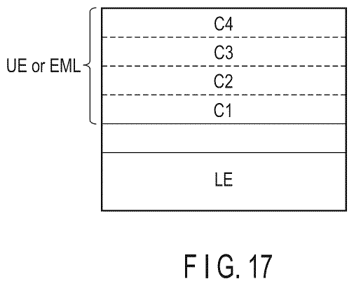

FIG. 17 is a diagram for explaining an upper electrode UE or a light emitting layer EML formed by the manufacturing device 200 of FIG. 16.

First, an upper electrode UE formed of a mixture of magnesium and silver is explained. In the upper electrode UE, the contained amount of magnesium is the greatest in the layer which is the closest to a lower electrode LE, and the contained amount of magnesium is the least in the layer which is the most distant from the lower electrode LE. In other words, a concentration gradient in which the contained amount of magnesium decreases with increasing distance from the lower electrode LE can be formed in the upper electrode UE.

Now, this specification explains a light emitting layer EML formed of a mixture of a host material and a dopant material is explained. In the light emitting layer EML, the concentration of dopant is the least in the layer which is the closest to the lower electrode LE, and the concentration of dopant is the greatest in the layer which is the most distant from the lower electrode LE. In other words, a concentration gradient in which the concentration of dopant increases with increasing distance from the lower electrode LE can be formed in the light emitting layer EML.

It should be noted that a concentration gradient in which the concentration of dopant decreases with increasing distance from the lower electrode LE may be formed in the light emitting layer EML.

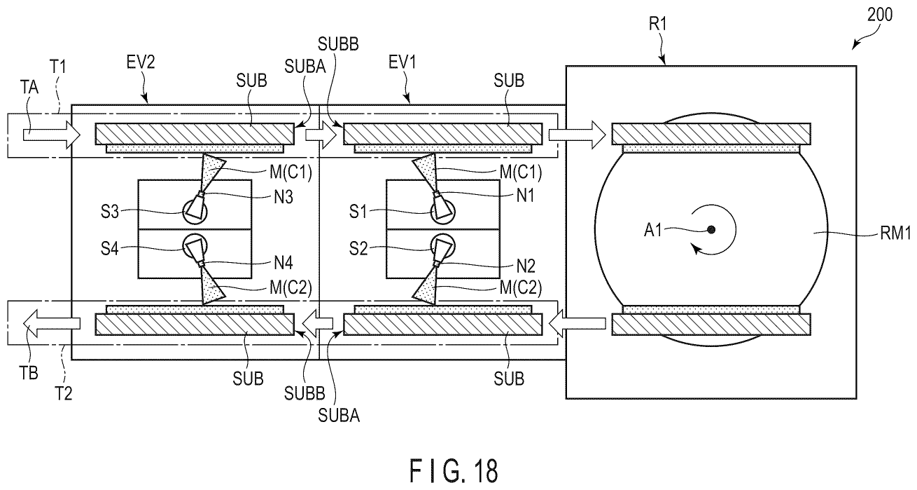

FIG. 18 is a diagram showing another configuration example of the manufacturing device 200.

The configuration example shown in FIG. 18 is different from that shown in FIG. 16 in respect that the nozzle of each evaporation source inclines.

For example, in the first evaporation chamber EV1, the nozzle N1 of the first evaporation source S1 inclines so as to face the other end SUBB of the processing substrate SUB, and the nozzle N2 of the second evaporation source S2 inclines so as to face the end SUBA of the processing substrate SUB.

In the second evaporation chamber EV2, the nozzle N3 of the third evaporation source S3 inclines so as to face the end SUBA of the processing substrate SUB, and the nozzle N4 of the fourth evaporation source S4 inclines so as to face the other end SUBB of the processing substrate SUB.

The materials M emitted from the first evaporation source S1, the second evaporation source S2, the third evaporation source S3 and the fourth evaporation source S4 are the same as each other and are mixtures each consisting of a plurality of types of materials. In the example shown in the figure, the composition ratios of the materials of the mixtures are different from each other between the first evaporation source S1 and the second evaporation source S2 and are different from each other between the third evaporation source S3 and the fourth evaporation source S4.

For example, in a case where the first evaporation chamber EV1 and the second evaporation chamber EV2 are configured to form an upper electrode UE, each material M is a mixture of magnesium as the first material and silver as the second material.

As another example, in a case where the first evaporation chamber EV1 and the second evaporation chamber EV2 are configured to form a light emitting layer EML, each material M is a mixture of a host material for carrier transport as the first material and a dopant material for light emission as the second material.

In these cases, concentration C1 of the first material of the mixture emitted from the first evaporation source S1 is higher than concentration C2 of the first material of the mixture emitted from the second evaporation source S2. Concentration C1 of the first material of the mixture emitted from the third evaporation source S3 is higher than concentration C2 of the first material of the mixture emitted from the fourth evaporation source S4. Concentration C1 of the first material of the mixture emitted from the first evaporation source S1 is substantially equal to concentration C1 of the first material of the mixture emitted from the third evaporation source S3. Concentration C2 of the first material of the mixture emitted from the second evaporation source S2 is substantially equal to concentration C2 of the first material of the mixture emitted from the fourth evaporation source S4.

In the configuration example shown in FIG. 18, effects similar to those of the configuration example shown in FIG. 11 are obtained.

In each of the configuration examples of the manufacturing device 200 described above, this specification explains a case in which the material M emitted from each evaporation source is a mixture consisting of two types of materials. However, the configuration is not limited to these examples. For example, the material M emitted from each evaporation source may be a mixture consisting of three types of materials. For example, when the light emitting layer EML is formed, a mixture of a first host material which is rich in an electron transport property, a second host material which is rich in a hole transport property and a dopant material may be emitted from each evaporation source.

Now, the manufacturing device 100 for forming the organic layer OR, upper electrode UE and cap layer CP shown in FIG. 10 is explained.

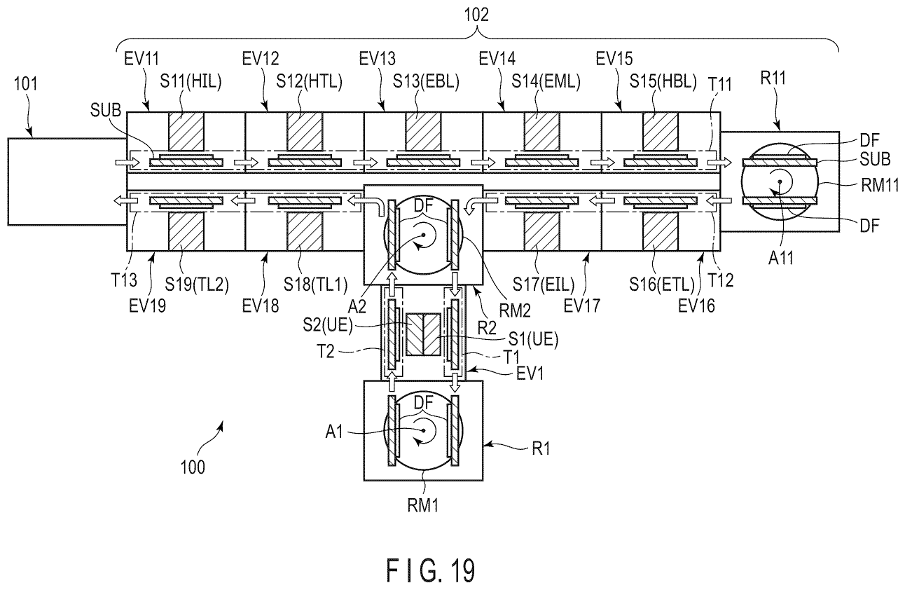

FIG. 19 is a diagram showing a configuration example of the manufacturing device 100.

The manufacturing device 100 is applied in, for example, the process of continuously forming the organic layer OR1, upper electrode UE1 and cap layer CP1 explained with reference to FIG. 5. As a matter of course, the manufacturing device 100 explained here can be also applied in the process of continuously forming the organic layer OR2, the upper electrode UE2 and the cap layer CP2 or the process of continuously forming the organic layer OR3, the upper electrode UE3 and the cap layer CP3.

The processing substrate SUB which is supposed to be carried in the manufacturing device 100 comprises the lower electrodes LE1, LE2 and LE3, the rib 5 and the partition 6 as explained with reference to FIG. 4.

The manufacturing device 100 comprises a processing portion 101 and an evaporation portion 102.

The processing portion 101 comprises a mechanism for performing various types of preprocesses such as a cleaning process, a drying process and a plasma process for the processing substrate SUB which was carried in. The processing portion 101 comprises a mechanism which sets the processing substrate SUB so as to be in a predetermined conveyance posture, a mechanism which secures the processing substrate SUB to a dedicated carrier by an electrostatic chuck, etc. Each conveyance path of the evaporation portion 102 is configured to convey a carrier. The processing portion 101 comprises a mechanism which releases the securing applied by the electrostatic chuck and removes the processing substrate SUB from the carrier, a mechanism which sets the processing substrate SUB so as to be in a predetermined posture, etc. For example, the posture of the processing substrate SUB carried in the processing portion 101 from outside is a horizontal posture. The conveyance posture of the processing substrate SUB conveyed in the evaporation portion 102 is a perpendicular posture.

The evaporation portion 102 comprises a first rotation chamber R1, a first evaporation chamber EV1, a second rotation chamber R2, a plurality of evaporation chambers EV11 to EV19 and a rotation chamber R11. A set consisting of the first rotation chamber R1 and the first evaporation chamber EV1 corresponds to the manufacturing device 200 shown in FIG. 11 or the manufacturing device 200 shown in FIG. 13.

The evaporation chambers EV11 to EV15 are arranged in a line. The evaporation chambers EV16 and EV17, the second rotation chamber R2 and the evaporation chambers EV18 and EV19 are arranged in a line. The second rotation chamber R2 is provided between the evaporation chamber EV17 and the evaporation chamber EV18. For example, the evaporation chamber EV17 corresponds to a third evaporation chamber, and the evaporation chamber EV18 corresponds to a fourth evaporation chamber.

The evaporation chambers EV11 and EV19 are connected to the processing portion 101. The evaporation chambers EV15 and EV16 are connected to the rotation chamber R11.

The first evaporation chamber EV1 is provided between the first rotation chamber R1 and the second rotation chamber R2. In the example shown in the figure, the first rotation chamber R1, the first evaporation chamber EV1 and the second rotation chamber R2 are arranged in a direction orthogonal to the direction in which the evaporation chambers EV16 and EV17 are arranged.

The evaporation chamber EV11 comprises an evaporation source S11. The evaporation source S11 is configured to emit a material for forming a hole injection layer HIL to a conveyance path T11.

The evaporation chamber EV12 comprises an evaporation source S12. The evaporation source S12 is configured to emit a material for forming a hole transport layer HTL to the conveyance path T11.

The evaporation chamber EV13 comprises an evaporation source S13. The evaporation source S13 is configured to emit a material for forming an electron blocking layer EBL to the conveyance path T11.

The evaporation chamber EV14 comprises an evaporation source S14. The evaporation source S14 is configured to emit a material for forming a light emitting layer EML to the conveyance path T11.

The evaporation chamber EV15 comprises an evaporation source S15. The evaporation source S15 is configured to emit a material for forming a hole blocking layer HBL to the conveyance path T11.

The evaporation chamber EV16 comprises an evaporation source S16. The evaporation source S16 is configured to emit a material for forming an electron transport layer ETL to a conveyance path T12.

The evaporation chamber EV17 comprises an evaporation source S17. The evaporation source S17 is configured to emit a material for forming an electron injection layer EIL to the conveyance path T12.

The evaporation chamber EV18 comprises an evaporation source S18. The evaporation source S18 is configured to emit a material for forming a first transparent layer TL1 to a conveyance path T13.

The evaporation chamber EV19 comprises an evaporation source S19. The evaporation source S19 is configured to emit a material for forming a second transparent layer TL2 to the conveyance path T13.

The conveyance paths T11 to T13 are provided inside the evaporation portion 102. The evaporation sources S11 to S19 are provided on the external side of the conveyance paths T11 to T13 in the evaporation portion 102. For example, when this specification particularly looks at the evaporation chambers EV11 and EV19, the conveyance paths T11 and T13 are located between the evaporation source S11 and the evaporation source S19. When this specification particularly looks at the evaporation chambers EV15 and EV16, the conveyance paths T11 and T12 are located between the evaporation source S15 and the evaporation source S16.

The first evaporation chamber EV1 comprises a first evaporation source S1 and a second evaporation source S2. The first evaporation source S1 and the second evaporation source S2 are located between a first conveyance path T1 and a second conveyance path T2 in the first evaporation chamber EV1. The first evaporation source S1 is configured to emit a material for forming an upper electrode UE to the first conveyance path T1. The second evaporation source S2 is configured to emit a material for forming an upper electrode UE to the second conveyance path T2.

The first rotation chamber R1 comprises a rotation mechanism RM1 which rotates 180° with the held processing substrate SUB. The second rotation chamber R2 comprises a rotation mechanism RM2 which rotates 90° with the held processing substrate SUB. The rotation chamber R11 comprises a rotation mechanism RM11 which rotates 180° with the held processing substrate SUB.

This specification hereinafter explains the manufacturing process in the manufacturing device 100.

First, a processing substrate SUB in which a lower electrode LE has been formed is carried in the processing portion 101. In the processing portion 101, a predetermined preprocess is performed for the processing substrate SUB.

Subsequently, the processing substrate SUB is carried in the evaporation chamber EV11. In the evaporation chamber EV11, the material emitted from the evaporation source S11 is deposited on the processing substrate SUB conveyed in the conveyance path T11. By this process, a hole injection layer HIL is formed on the lower electrode LE.

Subsequently, the processing substrate SUB is carried in the evaporation chamber EV12. In the evaporation chamber EV12, the material emitted from the evaporation source S12 is deposited on the processing substrate SUB conveyed in the conveyance path T11. By this process, a hole transport layer HTL is formed on the hole injection layer HIL.

Subsequently, the processing substrate SUB is carried in the evaporation chamber EV13. In the evaporation chamber EV13, the material emitted from the evaporation source S13 is deposited on the processing substrate SUB conveyed in the conveyance path T11. By this process, an electron blocking layer EBL is formed on the hole transport layer HTL.

Subsequently, the processing substrate SUB is carried in the evaporation chamber EV14. In the evaporation chamber EV14, the material emitted from the evaporation source S14 is deposited on the processing substrate SUB conveyed in the conveyance path T11. By this process, a light emitting layer EML is formed on the electron blocking layer EBL.

Subsequently, the processing substrate SUB is carried in the evaporation chamber EV15. In the evaporation chamber EV15, the material emitted from the evaporation source S15 is deposited on the processing substrate SUB conveyed in the conveyance path T11. By this process, a hole blocking layer HBL is formed on the light emitting layer EML.

Subsequently, the processing substrate SUB is carried in the rotation chamber R11. In the rotation chamber R11, the rotation mechanism RM11 holds the processing substrate SUB which was carried in. At this time, the rotation mechanism RM11 holds the processing substrate SUB in a state where an evaporated film DF faces the side opposite to a rotation axis A11. The rotation mechanism RM11 rotate 180° while holding the processing substrate SUB.

Subsequently, the processing substrate SUB is carried in the evaporation chamber EV16. In the evaporation chamber EV16, the material emitted from the evaporation source S16 is deposited on the processing substrate SUB conveyed in the conveyance path T12. By this process, an electron transport layer ETL is formed on the hole blocking layer HBL.

Subsequently, the processing substrate SUB is carried in the evaporation chamber EV17. In the evaporation chamber EV17, the material emitted from the evaporation source S17 is deposited on the processing substrate SUB conveyed in the conveyance path T12. By this process, an electron injection layer EIL is formed on the electron transport layer ETL.

Subsequently, the processing substrate SUB is carried in the second rotation chamber R2. In the second rotation chamber R2, the rotation mechanism RM2 holds the processing substrate SUB which was carried in. At this time, the rotation mechanism RM2 holds the processing substrate SUB in a state where the evaporated film DF faces a rotation axis A2. Subsequently, the rotation mechanism RM2 rotates 90° while holding the processing substrate SUB.

Subsequently, the processing substrate SUB is carried in the first evaporation chamber EV1. In the first evaporation chamber EV1, the material emitted from the first evaporation source S1 is deposited on the processing substrate SUB conveyed in the first conveyance path T1. By this process, the first layer of an upper electrode UE is formed on the electron injection layer EIL.

Subsequently, the processing substrate SUB is carried in the first rotation chamber R1. In the first rotation chamber R1, the rotation mechanism RM1 holds the processing substrate SUB which was carried in. At this time, the rotation mechanism RM1 holds the processing substrate SUB in a state where the evaporated film DF faces a rotation axis A1. The rotation mechanism RM1 rotates 180° while holding the processing substrate SUB.

Subsequently, the processing substrate SUB is carried in the first evaporation chamber EV1. In the first evaporation chamber EV1, the material emitted from the second evaporation source S2 is deposited on the processing substrate SUB conveyed in the second conveyance path T2. By this process, the second layer of the upper electrode UE is formed.

Subsequently, the processing substrate SUB is carried in the second rotation chamber R2. In the second rotation chamber R2, the rotation mechanism RM2 holds the processing substrate SUB which was carried in. At this time, the rotation mechanism RM2 holds the processing substrate SUB in a state where the evaporated film DF faces the rotation axis A2. Subsequently, the rotation mechanism RM2 rotates 90° while holding the processing substrate SUB.

Subsequently, the processing substrate SUB is carried in the evaporation chamber EV18. In the evaporation chamber EV18, the material emitted from the evaporation source S18 is deposited on the processing substrate SUB conveyed in the conveyance path T13. By this process, a first transparent layer TL1 is formed on the upper electrode UE.

Subsequently, the processing substrate SUB is carried in the evaporation chamber EV19. In the evaporation chamber EV19, the material emitted from the evaporation source S19 is deposited on the processing substrate SUB conveyed in the conveyance path T13. By this process, a second transparent layer TL2 is formed on the first transparent layer TL1.

Subsequently, the processing substrate SUB is carried in the processing portion 101. In the processing portion 101, a predetermined process is performed for the processing substrate SUB.

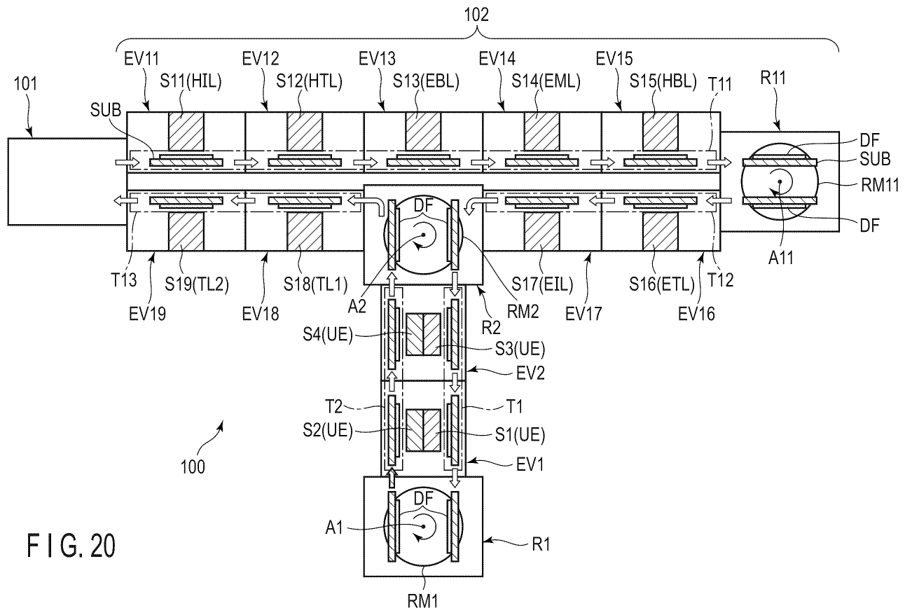

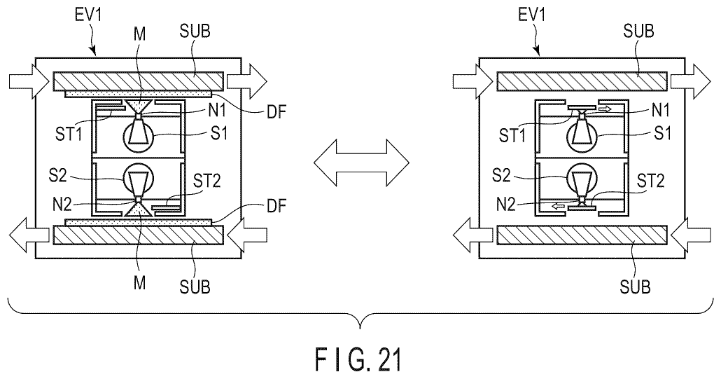

FIG. 20 is a diagram showing another configuration example of the manufacturing device 100.

The configuration example shown in FIG. 20 is different from that shown in FIG. 19 in respect that a second evaporation chamber EV2 is added between the first evaporation chamber EV1 and the second rotation chamber R2. A set consisting of the first rotation chamber R1, the first evaporation chamber EV1 and the second evaporation chamber EV2 corresponds to the manufacturing device 200 shown in FIG. 16 or the manufacturing device 200 shown in FIG. 18.

The second evaporation chamber EV2 comprises a third evaporation source S3 and a fourth evaporation source S4. The third evaporation source S3 and the fourth evaporation source S4 are located between the first conveyance path T1 and the second conveyance path T2 in the second evaporation chamber EV2. The third evaporation source S3 is configured to emit a material for forming an upper electrode UE to the first conveyance path T1. The fourth evaporation source S4 is configured to emit a material for forming an upper electrode UE to the second conveyance path T2.

The other configurations are the same as the manufacturing device 100 shown in FIG. 19, explanation thereof being omitted.

It should be noted that, in the manufacturing device 100 shown in FIG. 19, the evaporation chamber EV14 for the light emitting layer EML can be replaced by a set consisting of the first rotation chamber R1, the first evaporation chamber EV1 and the second rotation chamber R2. In the manufacturing device 100 shown in FIG. 20, the evaporation chamber EV14 for the light emitting layer EML can be replaced by a set consisting of the first rotation chamber R1, the first evaporation chamber EV1, the second evaporation chamber EV2 and the second rotation chamber R2.

FIG. 21 is a diagram showing another configuration example of the first evaporation chamber EV1.

The first evaporation chamber EV1 comprises a first shutter ST1 and a second shutter ST2. The first shutter ST1 and the second shutter ST2 can be individually driven.

The left side of the figure shows a state in which the first shutter ST1 and the second shutter ST2 are open. In this state, each of the material M emitted from the first evaporation source S1 and the material M emitted from the second evaporation source S2 reaches the processing substrate SUB.

The right side of the figure shows a state in which the first shutter ST1 and the second shutter ST2 are closed. The first shutter ST1 faces the nozzle N1 of the first evaporation source S1. The second shutter ST2 faces the nozzle N2 of the second evaporation source S2. In this state, the material M emitted from the first evaporation source S1 is blocked by the first shutter ST1 and does not reach the processing substrate SUB. Similarly, the material M emitted from the second evaporation source S2 is blocked by the second shutter ST2 and does not reach the processing substrate SUB.

For example, when the thickness of an evaporated film DF formed of the material M emitted from the first evaporation source S1 is confirmed, the first shutter ST1 is set to an open state, and the second shutter ST2 is set to a closed state. When a processing substrate SUB in which the deposition of the material M is not needed is conveyed to the first evaporation chamber EV1, both the first shutter ST1 and the second shutter ST2 are set to a closed state.

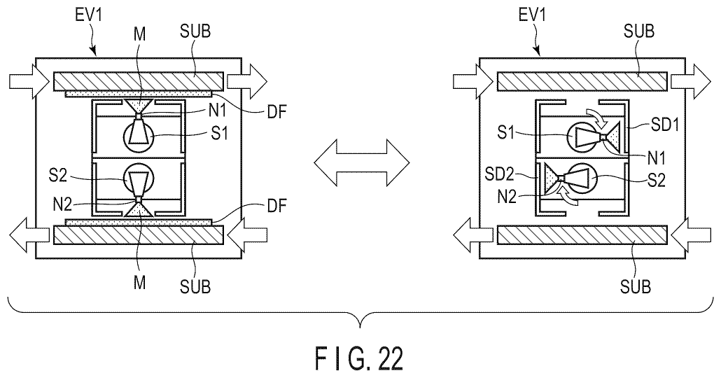

FIG. 22 is a diagram showing another configuration example of the first evaporation chamber EV1.

The first evaporation source S1 is surrounded by a first shield SD1 and is configured to rotate. The second evaporation source S2 is surrounded by a second shield SD2 and is configured to rotate.

The left side of the figure shows a state in which each of the nozzle N1 of the first evaporation source S1 and the nozzle N2 of the second evaporation source S2 faces the processing substrate SUB. In this state, each of the material M emitted from the first evaporation source S1 and the material M emitted from the second evaporation source S2 reaches the processing substrate SUB.

The right side of the figure shows a state in which the first evaporation source S1 and the second evaporation source S2 rotate 90° from the state of the left side of the figure. The nozzle N1 of the first evaporation source S1 faces the first shield SD1. The nozzle N2 of the second evaporation source S2 faces the second shield SD2. In this state, the material M emitted from the first evaporation source S1 is blocked by the first shield SD1 and does not reach the processing substrate SUB. Similarly, the material M emitted from the second evaporation source S2 is blocked by the second shield SD2 and does not reach the processing substrate SUB.

For example, when the thickness of an evaporated film DF formed of the material M emitted from the first evaporation source S1 is confirmed, the nozzle N1 of the first evaporation source S1 is set to a state in which the nozzle N1 faces the processing substrate SUB, and the nozzle N2 of the second evaporation source S2 is set to a state in which the nozzle N2 faces the second shield SD2. When a processing substrate SUB in which the deposition of the material M is not needed is conveyed to the first evaporation chamber EV1, the nozzle N1 of the first evaporation source S1 is set to a state in which the nozzle N1 faces the first shield SD1, and the nozzle N2 of the second evaporation source S2 is set to a state in which the nozzle N2 faces the second shield SD2.

It should be noted that the configuration example of the first evaporation chamber EV1 shown in FIG. 21 and FIG. 22 can be also applied to the second evaporation chamber EV2.

As explained above, the embodiments can provide a manufacturing device of a display device and a manufacturing method of a display device such that the cost can be reduced, and the installation space can be reduced.

All of the manufacturing devices and manufacturing methods that can be implemented by a person of ordinary skill in the art through arbitrary design changes to the manufacturing device and manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing device of a display device, comprising:
a first evaporation chamber comprising first and second evaporation sources located between a first conveyance path and a second conveyance path for conveying a processing substrate for a display device, the first evaporation source configured to emit a material to the first conveyance path, the second evaporation source configured to emit a material to the second conveyance path; and
a first rotation chamber comprising a rotation mechanism which rotates while holding the processing substrate carried out of the first conveyance path of the first evaporation chamber, and configured to carry out the processing substrate to the second conveyance path of the first evaporation chamber.

2. The manufacturing device of claim 1, wherein
a nozzle of the first evaporation source inclines so as to face an end of the processing substrate in a conveyance direction of the processing substrate relative to a normal of the processing substrate, and
a nozzle of the second evaporation source inclines so as to face the other end of the processing substrate in the conveyance direction of the processing substrate relative to the normal of the processing substrate.

3. The manufacturing device of claim 1, wherein
the material emitted from the first evaporation source is same as the material emitted from the second evaporation source.

4. The manufacturing device of claim 1, wherein
the material emitted from each of the first evaporation source and the second evaporation source is a mixture including a first material and a second material, and
a composition ratio between the first material and the second material differs between the first evaporation source and the second evaporation source.

5. The manufacturing device of claim 4, wherein
the first material is magnesium, and the second material is silver, and
concentration of the first material in the mixture emitted from the first evaporation source is higher than concentration of the first material in the mixture emitted from the second evaporation source.

6. The manufacturing device of claim 4, wherein
the first material is a host material for carrier transport, and the second material is a dopant material for light emission, and
concentration of the first material in the mixture emitted from the first evaporation source is higher than concentration of the first material in the mixture emitted from the second evaporation source.

7. The manufacturing device of claim 4, wherein
the first material is a host material for carrier transport, and the second material is a dopant material for light emission, and
concentration of the first material in the mixture emitted from the second evaporation source is higher than concentration of the first material in the mixture emitted from the first evaporation source.

8. The manufacturing device of claim 1, further comprising a second evaporation chamber comprising third and fourth evaporation sources located between the first conveyance path and the second conveyance path, the third evaporation source configured to emit a material to the first conveyance path, the fourth evaporation source configured to emit a material to the second conveyance path, wherein
the first evaporation chamber is provided between the first rotation chamber and the second evaporation chamber.

9. The manufacturing device of claim 1, further comprising a third evaporation chamber, a fourth evaporation chamber and a second rotation chamber provided between the third evaporation chamber and the fourth evaporation chamber, wherein
the second rotation chamber
rotates the processing substrate so as to convey the processing substrate carried out of the third evaporation chamber to the first conveyance path, and
rotates the processing substrate so as to convey the processing substrate carried out of the second conveyance path to the fourth evaporation chamber.

10. A manufacturing method of a display device, comprising:
preparing a processing substrate by forming a lower electrode above a substrate, forming a rib comprising an aperture overlapping the lower electrode, and forming a partition including a lower portion located on the rib and an upper portion located on the lower portion and protruding from a side surface of the lower portion;
carrying the processing substrate in a first conveyance path of a first evaporation chamber;
depositing a material emitted from a first evaporation source on the processing substrate in the first evaporation chamber;
rotating the processing substrate carried out of the first evaporation chamber;
carrying the processing substrate in a second conveyance path of the first evaporation chamber;
depositing a material emitted from a second evaporation source to the processing substrate in the first evaporation chamber; and
carrying the processing substrate out of the first evaporation chamber, wherein
the material emitted from each of the first evaporation source and the second evaporation source is a mixture including a first material and a second material, and
a composition ratio between the first material and the second material differs between the first evaporation source and the second evaporation source.

11. The manufacturing method of claim 10, further comprising forming an organic layer including a light emitting layer on the lower electrode before carrying the processing substrate in the first evaporation chamber.

12. The manufacturing method of claim 11, wherein
the first material is magnesium, and the second material is silver, and
concentration of the first material in the mixture emitted from the first evaporation source is higher than concentration of the first material in the mixture emitted from the second evaporation source.

13. The manufacturing method of claim 10, further comprising forming part of an organic layer on the lower electrode before carrying the processing substrate in the first evaporation chamber.

14. The manufacturing method of claim 13, wherein
the first material is a host material for carrier transport, and the second material is a dopant material for light emission, and
concentration of the first material in the mixture emitted from the first evaporation source is higher than concentration of the first material in the mixture emitted from the second evaporation source.

15. The manufacturing method of claim 13, wherein
the first material is a host material for carrier transport, and the second material is a dopant material for light emission, and
concentration of the first material in the mixture emitted from the second evaporation source is higher than concentration of the first material in the mixture emitted from the first evaporation source.

16. The manufacturing method of claim 10, wherein
a nozzle of the first evaporation source inclines so as to face an end of the processing substrate in a conveyance direction of the processing substrate relative to a normal of the processing substrate, and
a nozzle of the second evaporation source inclines so as to face the other end of the processing substrate in the conveyance direction of the processing substrate relative to the normal of the processing substrate.
